(19) United States
(12) Patent Application Publication
(10) Pub. No.: US 2013/0185612 A1
(43) Pub. Date: Jul. 18, 2013

(54) FLASH MEMORY SYSTEM AND READ METHOD OF FLASH MEMORY SYSTEM

(71) Applicant: Samsung Electronics Co., Ltd., Suwon-si (KR)

(72) Inventors: Sang-hoon Lee, Yongin-si (KR); Sung-hwan Bae, Seoul (KR); Jong-nam Baek, Hwaseong-si (KR); Hyun-seok Kim, Goyang-si (KR); Sung-bin Kim, Seoul (KR)

(73) Assignee: Samsung Electronics Co., Ltd., Suwon-si (KR)

(21) Appl. No.: 13/745,105

(22) Filed: Jan. 18, 2013

Related U.S. Application Data
(63) Continuation-in-part of application No. 13/398,204, filed on Feb. 16, 2012.
Application No. 13/398,204 is a continuation-in-part of application No. 13/429,326, filed on Mar. 24, 2012.

(30) Foreign Application Priority Data
Jan. 18, 2012 (KR) 10-2012-0005837

(51) Int. Cl. G06F 11/07; H03M 13/13

(52) U.S. Cl. CPC G06F 11/0751; H03M 13/13; G06F 11/0793
USPC 714/773; 714/799; 714/746

(57) ABSTRACT

A read method in a flash memory system containing a flash memory and a memory controller includes updating a selected one of indexes of a selected one of blocks of the flash memory, in a wear-out table for indexing each of the blocks of the flash memory, and setting a start read level to start read retry on the selected block by referring to a read retry table corresponding to a wear-out degree included in the selected index when a current request of read retry on the selected block is received.

### REFERENCE TO PRIORITY APPLICATIONS

This application is a continuation-in-part of application Ser. No. 13/398,204 filed Feb. 16, 2012, and a continuation-in-part of application Ser. No. 13/429,326, filed Mar. 24, 2012, which claims priority to Korean Patent Application No. 10-2012-0005837, filed Jan. 18, 2012 in the Korean Intellectual Property Office, the disclosures of which are hereby incorporated herein by reference in their entirety.

### FIELD

This invention relates to flash memory systems and read methods of flash memory systems and, more particularly, to flash memory systems which may reduce overhead of systems by quickly and accurately correcting read errors so as to improve read reliability and related read methods.

### BACKGROUND

Flash memory systems have been scaled down in response to requests for higher integration, whereas the number of bits to be stored in each memory cell has increased. Thus, a read margin between program states decreases so that a read error is frequently generated. Thus, methods for quickly and accurately performing read error correction are widely being developed.

### SUMMARY

The inventive concept provides a flash memory system which may reduce overhead of a system by quickly and accurately correcting a read error so as to improve read reliability, and a read method of a flash memory system.

According to an aspect of the inventive concept, there is provided a read method in a flash memory system including a flash memory and a memory controller includes updating a selected one of indexes of a selected one of blocks of the flash memory, in a wear-out table for indexing each of the blocks of the flash memory, and setting a start read level to start read retry on the selected block by referring to a read retry table corresponding to a wear-out degree included in the selected index when a current request of read retry on the selected block is received.

The read retry table corresponding to the wear-out degree included in the selected index may be one of read retry tables separately provided for each endurance state of the flash memory.

The read retry table corresponding to the wear-out degree included in the selected index may have a read environment of the flash memory as an index.

The read environment may be at least one of a retention characteristic and a read disturb characteristic of the flash memory.

The selected index may include a wear-out degree of the selected block, and information of an index corresponding to a read level at which a read error is corrected by a previous request for read retry on the selected block among the indexes of the read retry table.

The read method may further include repeating a read operation at each voltage level from the start read level to a last read level of a last index of a read retry table corresponding to a wear-out degree included in the selected index, until an error that is a basis for a current request of the read retry is corrected.

The read method may further include starting a read correction operation that is different from read retry when the error is not corrected by a read operation at the last read level of the last index of a read retry table corresponding to a wear-out degree included in the selected index.

The read correction operation that is different from read retry may be a read correction operation by soft decision in a low density parity check code (LDPC) method.

According to another aspect of the inventive concept, there is provided a memory system includes a flash memory comprising a plurality of blocks and detecting information about a state of a selected block in response to a first command, and a memory controller transmitting the first command to the flash memory and setting a read level to start read retry on the selected block by referring to a read retry table corresponding to the information about a state, of read retry tables separately included for each endurance state, when a current request of read retry on the selected block is received.

Each of the read retry tables may include at least one of a retention characteristic and a read disturb characteristic of the flash memory as an index.

The memory controller may update a selected index on the selected block of the indexes in a wear-out table for indexing each of the blocks of the flash memory based on the state information.

The memory system may further include an error control unit for setting a read level to start read retry on the selected block based on index information of a read retry table corresponding to a previous request of read retry included in the selected index.

The first command may be an erase command.

The state information in response to the erase command may correspond to an incremental step pulse erase (ISPE) loop count value used to erase the selected block.

The memory system may be included in a solid state drive.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart for explaining a read method of a flash memory system according to an exemplary embodiment of the present inventive concept;

FIG. 2 is a block diagram of a flash memory system according to an exemplary embodiment of the present inventive concept;

FIGS. 3A and 3B illustrate a memory cell array of the flash memory of FIG. 2;

FIGS. 4A-4C are graphs showing distributions of a memory cell of the flash memory of FIG. 2;

FIG. 5 illustrates an example of a first command and state information of FIG. 2;

FIG. 6 illustrates an example of a wear-out table of FIG. 2;

FIG. 7 illustrates an example of a read retry table of FIG. 2;

FIG. 8 illustrates an example of an index of the wear-out table of FIG. 6;

FIG. 9 illustrates an example of a plurality of read retry tables of FIG. 7;

FIG. 10 is a flowchart for explaining a read method of a flash memory system according to another exemplary embodiment of the present inventive concept;

FIG. 11 is a block diagram of a computing system according to an exemplary embodiment of the present inventive concept;

FIG. 12 is a block diagram of a memory card according to an exemplary embodiment of the present inventive concept;

FIG. 13 illustrates an SSD according to an exemplary embodiment of the present inventive concept;

FIG. 14 illustrates a server system including an SSD and a network system; and

FIG. 15 illustrates an error control unit.

### DETAILED DESCRIPTION OF THE EMBODIMENTS

Exemplary embodiments are provided to further completely explain the present inventive concept to one skilled in the art to which the present inventive concept pertains. However, the present inventive concept is not limited thereto and it will be understood that various changes in form and details may be made therein without departing from the spirit and scope of the following claims. That is, descriptions on particular structures or functions may be presented merely for explaining exemplary embodiments of the present inventive concept.

In the following description, when a layer is described to exist on another layer, the layer may exist directly on the other layer or a third layer may be interposed therebetween. Also, the thickness or size of each layer illustrated in the drawings is exaggerated for convenience of explanation and clarity. Like references indicate like constituent elements in the drawings. As used in the present specification, the term “and/or” includes any one of listed items and all of at least one combination of the items.

The terms used in the present specification are used for explaining a specific exemplary embodiment, not limiting the present inventive concept. Thus, the expression of singularity in the present specification includes the expression of plurality unless clearly specified otherwise in context. Also, the terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In the present specification, the terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the present inventive concept, a first member, part, area, layer, or portion may refer to a second member, part, area, layer, or portion.

Hereinafter, the exemplary embodiments of the present inventive concept are described in detail with reference to the accompanying drawings. In the drawings, the illustrated shapes may be modified according to, for example, manufacturing technology and/or tolerance. Thus, the exemplary embodiment of the present inventive concept may not be construed to be limited to a particular shape of a part described in the present specification and may include a change in the shape generated during manufacturing, for example.

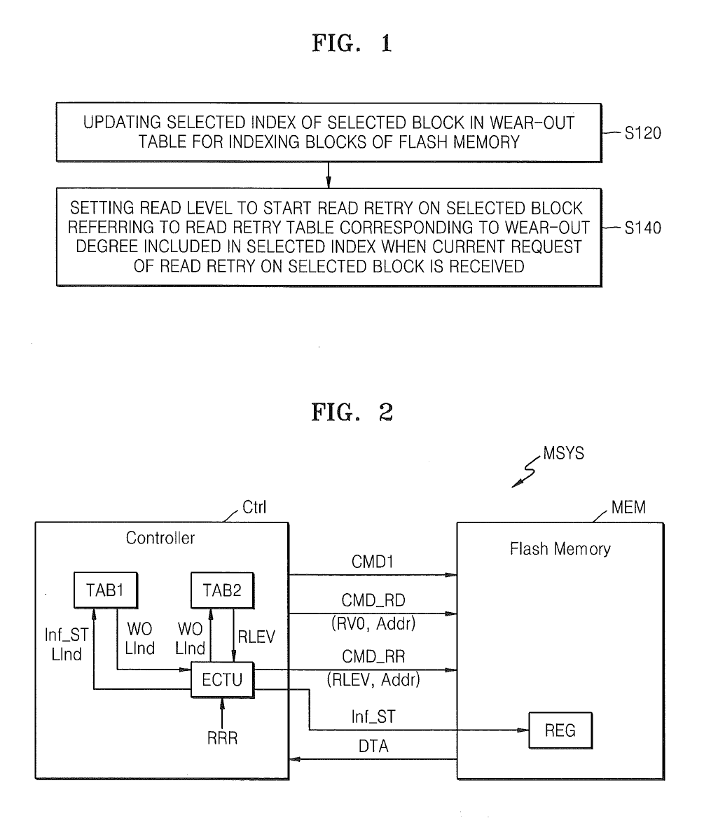

FIG. 1 is a flowchart for explaining a read method of a flash memory system MSYS according to an exemplary embodiment of the present inventive concept. FIG. 2 is a block diagram of a flash memory system according to an exemplary embodiment of the present inventive concept. Referring to FIGS. 1 and 2, the flash memory system MSYS according to the present exemplary embodiment includes a flash memory MEM and a controller Ctrl. A read method of the MSYS includes an operation of updating a selected index of a selected block in a wear-out table for indexing blocks of the MEM (S120), and an operation of setting a read level RLEV to start read retry on the selected block referring to a read retry table corresponding to a wear-out degree included in the selected index when a current request of read retry on the selected block is received (S140).

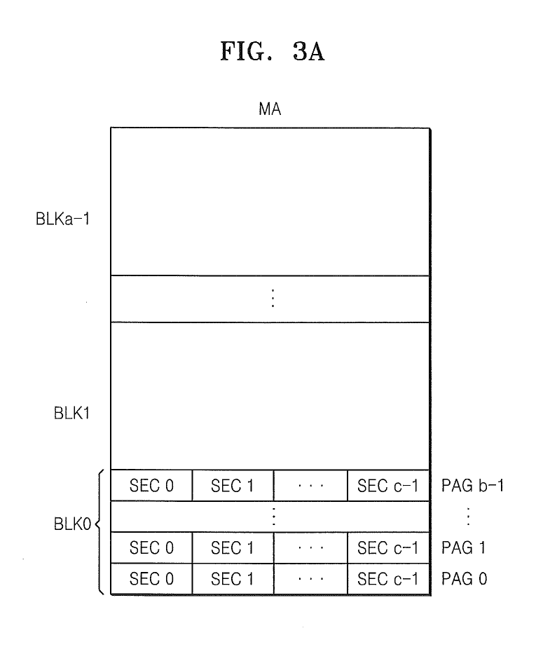

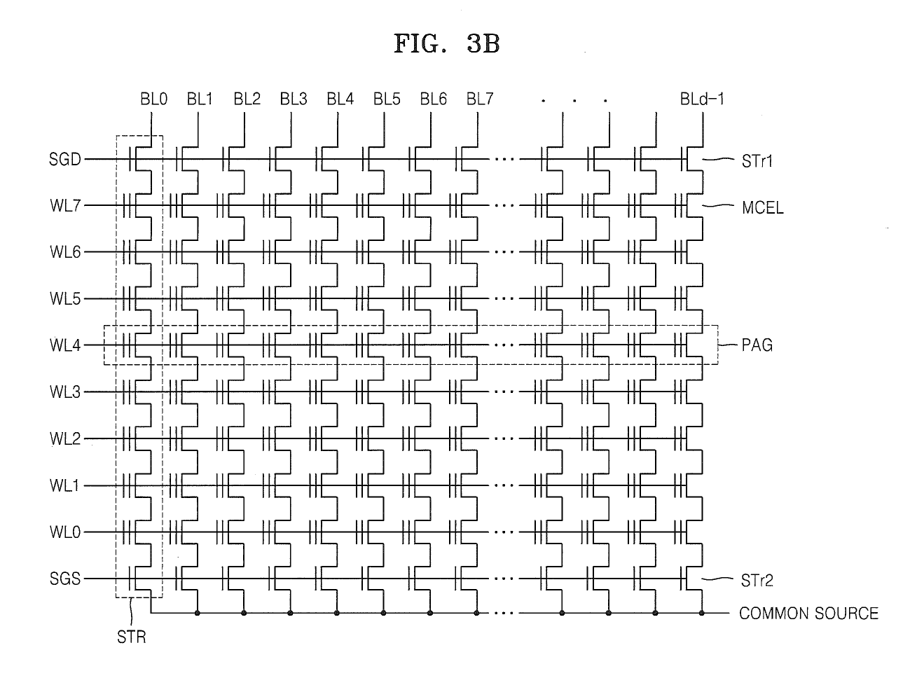

In detail, the MEM in response to a read command CMD_RD outputs data DTA stored in a memory cell array (not shown). The MEM applies an initial read voltage RV₀ to memory cells (not shown) corresponding to addresses Addr of the CMD_RD to output the DTA stored in the corresponding memory cells to the Ctrl. The MEM of the MSYS according to the present exemplary embodiment may include a cell array MA having a structure of FIG. 3A. The MA may include “a” number of blocks BLK0-BLKa-1 where “a” is an integer that is equal to or greater than 2. Each of the blocks BLK0-BLKa-1 may include “b” number of pages PAG0-PAGb-1 where “b” is an integer that is equal to or greater than 2. Each of the pages PAG0-PAGb-1 may include “c” number of sectors SEC0-SECc-1 where “c” is an integer that is equal to or greater than 2. In FIG. 3A, for convenience of explanation, the pages PAG0-PAGb-1 and the sectors SEC0-SECc-1 are illustrated only for the block BLK0, but the other blocks BLK1-BLKa-1 may have the same structure as the block BLK0.

When the MA according to the present exemplary embodiment is a memory cell array of the above-described NAND flash memory, each of the blocks BLK0-BLKa-1 of FIG. 3A may be provided as an example of FIG. 3B. Referring to FIG. 3B, each of the blocks BLK0-BLKa-1 may be provided as d-number of strings STRs, where “d” is an integer equal to or greater than 2, to which 8 memory cells MCELs are serially connected in a direction of a plurality of bit lines BL0-BLd-1. Each string STR may include a drain select transistor Str1 and a source select transistor Str2 that are connected to both ends of the serially connected MCELs.

In a NAND flash memory device configured as illustrated in FIG. 3B, erase is performed in units of blocks and a program is executed in units of pages PAGs respectively corresponding to word lines WL0-WL7. FIG. 3B illustrates an example in which 8 pages PAGs are provided corresponding to 8 word lines WL0-WL7 in one block. However, the blocks BLK0-BLKa-1 of the MA according to the present exemplary embodiment may be provided with the number of memory cells and pages different from that of the MCELs and PAGs of FIG. 3B. Also, the MEM of FIG. 2 may be provided with a plurality of memory cell arrays performing the same operation with the same structure of the above-described MA.

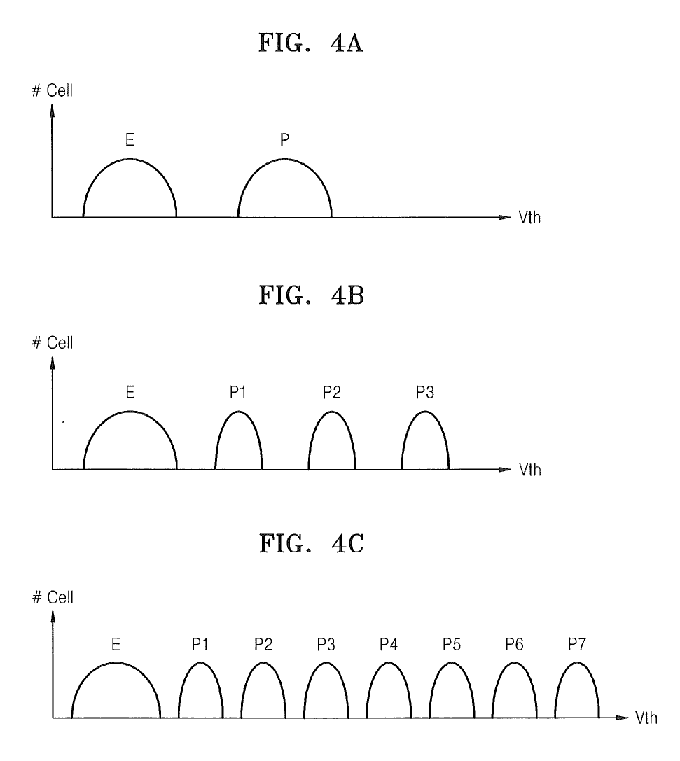

The MCELs of the semiconductor memory device configured as FIG. 3B may have a threshold voltage Vth included in one of the distributions of FIGS. 4A-4C. FIG. 4A shows a cell distribution in a single-level cell SLC flash memory in which each MCEL is programmed by one bit. FIG. 4B shows a cell distribution in a 2-bit multi-level cell MLC flash memory in which each MCEL is programmed by two bits. FIG. 4C shows a cell distribution in a 3-bit multi-level cell MLC flash memory in which each MCEL is programmed by three bits.

For an SLC flash memory, each MCEL of the MA of FIG. 3B has a threshold voltage that is included in one of an erase state E and a program state P according to a value of programmed data, as shown in FIG. 4A. For a 2-bit MLC flash memory, each MCEL of the MA of FIG. 3B has a threshold voltage that is included in any one of an erase state E and first to third program states P1 to P3. For a 3-bit MLC flash memory, each MCEL of the MA of FIG. 3B has a threshold voltage that is included in any one of an erase state E and first to seven program states P1 to P7. However, the present inventive concept is not limited thereto and, although it is not shown in FIGS. 4A-4C, each MCEL of the MA of FIG. 3B may be programmed by four or more bits. Also, the MEM of FIG. 1 may include the MCEL that is programmed by different number of bits.

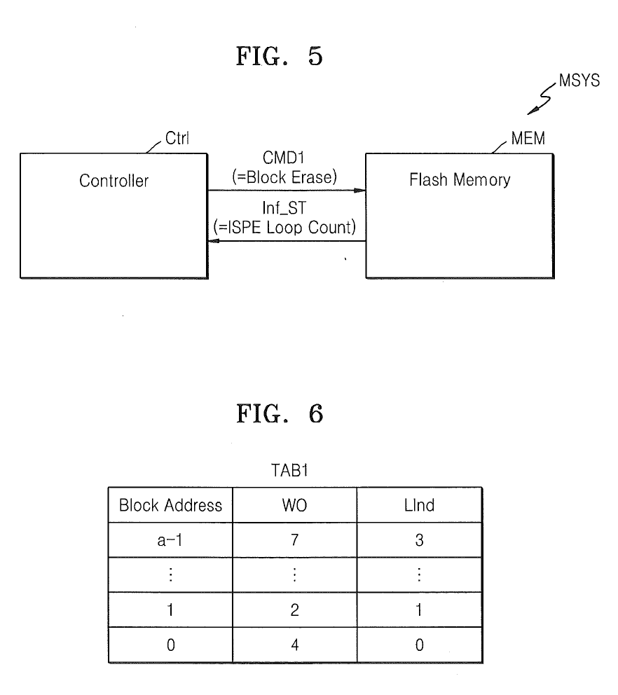

Referring back to FIG. 2, the MEM receives a first command CMD1 from the Ctrl. The CMD1 may be an erase command as illustrated in FIG. 5. The CMD1 includes an identifier of a block to erase, for example, an address of a block. For example, the CMD1 may be an erase command on the block BLK0 of FIG. 3A. However, the present inventive concept is not limited thereto and the CMD1 may be a program command.

The MEM in response to the CMD1 performs a corresponding operation. In this example, the MEM may perform an erase operation on the block BLK0 of FIG. 3A. The erase operation according to the present exemplary embodiment may be performed by applying erase voltage pulses having voltage levels that are sequentially increased until all cells of a block to erase are erased, that is, all cells of a corresponding block become an erase state E of FIG. 4. A scheme using erase voltage pulses having voltage levels that sequentially increase is referred to as an incremental step pulse erase (ISPE) method.

The MEM detects state information Inf_ST from a result of performance of the CMD1. In this example, the MEM may detect an ISPE loop count value as the Inf_ST as illustrated in FIG. 5. The ISPE loop count value is the number of erase voltage pulses consumed when a selected block is erased in response to an erase command. For example, in erasing the block BLK0 of FIG. 3A, if 5 erase voltage pulses that sequentially increase have been used, “5” that is an ISPE loop count value on the block BLK0 may be detected as the Inf_ST about the block BLK0. The MEM may store the Inf_ST in a register REG.

The ISPE loop count value may correspond to a wear-out degree of a selected block. For example, when the ISPE loop count value increases, it may be determined that a wear-out degree of the selected block has increased. However, the present inventive concept is not limited thereto and, if the CMD1 is a program command, the Inf_ST may be the number of program pulses consumed in programming a corresponding page in an incremental step pulse program (ISPP) method.

Referring to FIG. 2 again, the MEM transmits the Inf_ST to the Ctrl. The Ctrl may be provided with an error control unit ECTU. The ECTU may update a wear-out table TAB1 based on the Inf_ST. The TAB1 may be loaded in a system memory, for example, an SRAM (not shown), included in the Ctrl.

FIG. 6 illustrates an example of the TAB1. Referring to FIG. 6, the TAB1 according to the present exemplary embodiment may use a block identifier (block address) as an index of the table. For example, the index of the TAB1 may be addresses 0 to a-1 of the blocks BLK0 to BLKa-1 of FIG. 3A. The TAB1 may also contain a wear-out degree corresponding to the Inf_ST. In the above-described exemplary embodiment, the wear-out degree may be the ISPE loop count value of the selected block. FIG. 6 illustrates an example in which the wear-out degree of index 0 of the TAB1 is 4, the wear-out degree of index 1 of the TAB1 is 2, and the wear-out degree of index a-1 of the TAB1 is 7. When the wear-out degree denotes the ISPE loop count value of a selected block, FIG. 6 illustrates examples in which the wear-out degrees of the blocks BLK0, BLK1, and BLKa-1 are 4, 2, and 7, respectively. That is, FIG. 6 illustrates cases in which 4, 2, and 7 erase pulses are used to erase the blocks BLK0, BLK1, and BLKa-1, respectively.

The ECTU of the Ctrl of FIG. 2 updates the content of an index corresponding to the Inf_ST in the TAB1 of FIG. 6 when the Inf_ST is received. For example, the Inf_ST is by the CMD1 on the block BLKa-1, the ECTU updates the content of an index of the block BLKa-1 of the TAB1. For example, the ECTU may update a wear-out degree of 7 of the index a-1 of the TAB1 to a wear-out degree of 8.

The TAB1 according to the present exemplary embodiment may also include index information about a read retry table TAB2. The TAB2 may use a read environment of the MEM or the MSYS as an index. The read environment of the MEM or the MSYS refers to a characteristic affecting read of data programmed in the MEM, such as a retention characteristic or a read disturb characteristic of a memory. For example, a retention or a read disturb causes that wrong data that is different from the programmed data may be read by. The TAB2 may be loaded in a system memory, for example, an SRAM (not shown), included in the Ctrl, as illustrated in FIG. 1.

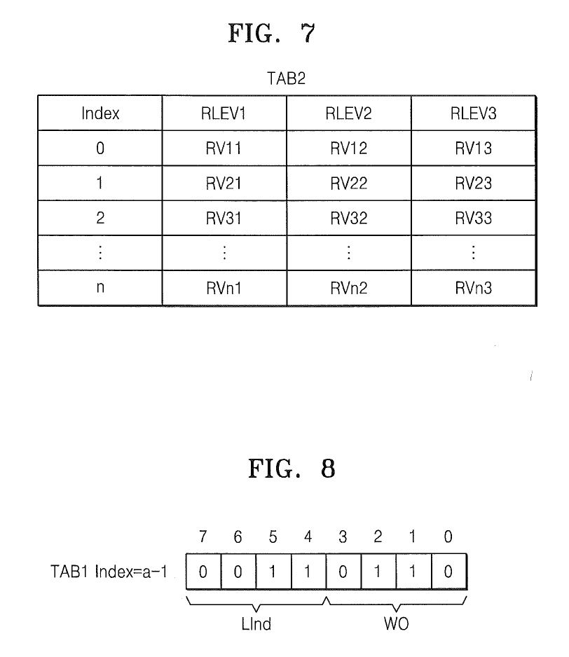

FIG. 7 illustrates an example of the TAB2. Indexes 0 to n of the TAB2 may denote the above-described read environments. For example, index 0 may denote a first state of the read disturb and index 1 may denote a second state of the read disturb. Index n may denote a first state of the retention.

The TAB2 includes a value of a read level for each index. The read level refers to a level of a read voltage applied to a page during a read retry operation on a selected block, that is, the corresponding page included in the selected block. The read retry operation is performed in the MEM upon a read retry request generated when an error is detected during the read of data programmed in the MEM. That is, it is the read retry to perform a read operation again by changing a read level when an error is generated in the read operation by a read voltage of a set level. For reference, a read error may be detected by an error checking and correction (ECC) engine (not shown). The ECC engine may be included inside or outside the Ctrl. The ECC may transmit a read retry request RRR to the ECTU of FIG. 2.

The ECTU according to the present exemplary embodiment may perform a read retry operation by changing a voltage level of a read voltage from a read level of any one index to a read level of an index that continues, until a read operation of the TAB2 is normally completed, that is, a read error is corrected.

Each index of the TAB2 may include a plurality of read levels because an MLC flash memory, for example, requires a plurality of read levels in reading out an MLC. For example, three other read voltages are needed to distinguish four states as illustrated in FIG. 4B. FIG. 7 illustrates an example that each index includes three read levels.

Referring to FIGS. 2, 6, and 7, the ECTU according to the present exemplary embodiment sets a read level to start read retry by referring to a read retry table index included in a selected index (index of a selected block) of the TAB1 when read retry is performed, that is, a read error is generated.

When a read command CMD_RD is issued for the block BLK1, since a selected index in the TAB1 is index 1, the ECTU sets a read level to start read retry as a read level included in index 1 of the TAB2 by referring to read retry table index 1 that is included in the index 1 in the TAB1. In the example of FIG. 7, the index 1 of the TAB2 includes read levels of RV21, RV22, and RV23. In this case, the ECTU starts a read retry operation by changing the read voltage set for the CMD_RD to the read levels of RV21, RV22, and RV23 of the index 1 of the TAB2. As described above, when the read error is not corrected by the read level of the index 1 of the TAB2, the ECTU performs again read retry with read levels RV31, RV32, and RV33 of the next index (index 2) of the TAB2. The ECTU repeats the above operation to the last index n of the TAB2 until the read error is corrected.

Although FIG. 2 illustrates that the ECTU directly performs read retry CMD_RR, the ECTU may provide information about the read level of read retry to a separate unit for performing read control that is included in the Ctrl. Also, although FIG. 2 illustrates the CMD_RR as being distinguished from the CMD_RD, this is mere illustration of conceptual distinguishment between the read command and the read retry. That is, the CMD_RR may be a CMD_DD with an initial read voltage RV0 changed to a read level RLEV.

FIG. 8 illustrates an example of information included in an index of the wear-out table of FIG. 6. Referring to FIGS. 6 and 8, each index of the TAB1 may include information of 1 byte. Of the 1 byte, 4 bits may refer to information about a wear-out degree and the other 4 bits may refer to information about a read retry table index. FIG. 8 illustrates an example in which a wear-out degree “7” of index a-1 and read retry table index “3” of TAB1 are indicated by bits 0 to 3 and bits 4 to 7, respectively.

Referring back to FIG. 2, the ECTU according to the present exemplary embodiment updates read retry table index information Lind included in each index of the TAB1 according to a result of a read retry operation. For example, when read retry of the selected block BLK1 is completed at a read level of index 2 of the TAB12 of FIG. 7, that is, a read error on the block BLK1 is corrected by the read level of index 2 of the TAB2 of FIG. 7, the ECTU may update the read retry table index of the index 1 of the TAB1 from 1 to 2.

As described above, when read retry is requested again, that is, a current request on read retry is received, the ECTU starts read retry at a read level of a retry table index included in an index of the TAB1 on a corresponding block. For example, when read retry on the block BLK1 is requested again after the read retry table index of the index 1 of the TAB1 of FIG. 6 for the BLK 1 is updated, the ECTU may start read retry at a read level of the index 2 of the TAB2.

As such, according to the memory system and the read method thereof according to the present exemplary embodiment, since a read level is set by reflecting a recent read retry result to the next read retry, the frequency of read retry may be reduced. Accordingly, according to the memory system and the read method thereof according to the present exemplary embodiment, read performance of the memory system may be improved.

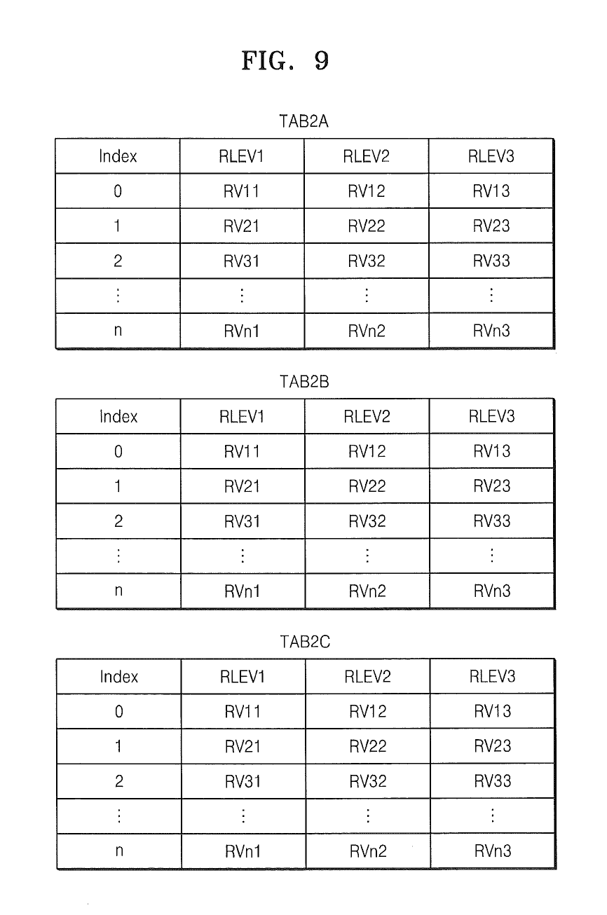

Referring back to FIG. 2, the ECTU according to the present exemplary embodiment may first select one of a plurality of read retry tables in setting a read level of read retry. As illustrated in FIG. 9, when three read retry tables TAB2A-TAB2C exist in the MSYS according to the present exemplary embodiment, the ECTU first selects a read retry table corresponding to a wear-out degree WO included in a selected index of the TAB1 among the TAB2A-TAB2C. Although the read levels of the TAB2A-TAB2C are indicated by the same reference numerals in FIG. 9, the values thereof are different from one another.

The wear-out degree is related to endurance of the MEM or each block. That is, the wear-out degree may vary according to endurance of each block. Accordingly, the TAB2A-TAB2C are separately provided according to an endurance state of the MEM. The endurance of a flash memory may be indicated by a program/erase (P/E) cycle. For example, the first read retry table TAB2A of FIG. 9 is a read retry table for a P/E cycle that is less than 1K, the second read retry table TAB2B of FIG. 9 is a read retry table for a P/E cycle that is equal to or greater than 1K and less than 2K, and the third read retry table TAB2C of FIG. 9 is a read retry table for a P/E cycle that is equal to or greater than 2K and less than 3K. Alternatively, the first read retry table TAB2A of FIG. 9 is a read retry table for a P/E cycle that is less than 1K, the second read retry table TAB2B of FIG. 9 is a read retry table for a P/E cycle that is equal to or greater than 1K and less than 3K, and the third read retry table TAB2C of FIG. 9 is a read retry table for a P/E cycle that is equal to or greater than 3K and less than 5K. The present inventive concept is not limited thereto and the read retry tables according to the present exemplary embodiment may be set to a different number of P/E cycles.

As the WO included in a selected index of the TAB1 according to the present exemplary embodiment is changed, the TAB2 corresponding to the WO before change may be different from the TAB2 corresponding to the WO after change. For example, when the WO before change of index 0 of the TAB1 has a P/E cycle that is less than 1K, as program/erase operations on a block corresponding to the index 0 of the TAB1 increase, the WO of the index 0 may have a P/E cycle that is equal to or greater than 0. In this example, the ECTU may change the read retry table to be searched corresponding to the WO of the index 0 from the TAB2A to the TAB2B of FIG. 9. When the read retry table is changed as such, the Lind on an index of a WO table may be initialized to 0.

When read retry is requested for a selected block, the ECTU selects any one of the read retry tables based on the WO of a selected index of the TAB1. For example, when the WO of the index 1 of FIG. 6 for the BLK1 is 2, the ECTU may perform a read retry operation on the BLK1 by referring to the TAB2A having a P/E cycle of 1K among the TAB2A to TAB2C.

According to the memory system and the read method thereof according to the present exemplary embodiment, in an environment in which a read error increases and a read retry entry time point becomes early due to high integration of a flash memory, since read retry is performed by referring to a read retry table separately provided for each endurance, the frequency of read retries may be reduced. Accordingly, system overhead according to the setting of a read level may be reduced. As a result, according to the memory system and the read method thereof according to the present exemplary embodiment, system resources may be saved and the time for read retry may be reduced.

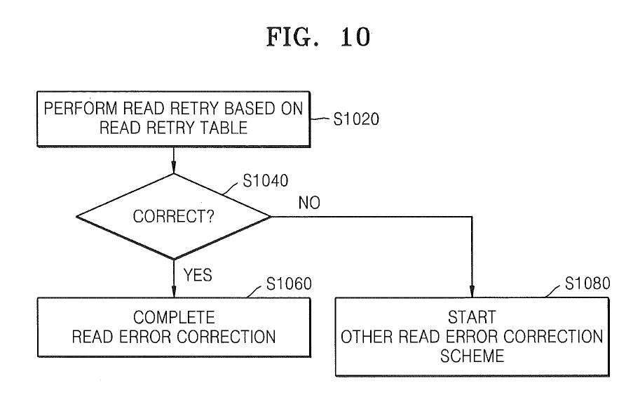

FIG. 10 is a flowchart for explaining a read method of a flash memory system according to another exemplary embodiment of the present inventive concept. Referring to FIGS. 2 and 10, the read method according to the present exemplary embodiment read retry I performed based on the TAB2 by the above-described read method of FIG. 1 (S1020). That is, a selected index of a selected block is updated, and a read level to start read retry on the selected block is set by referring to a read retry table corresponding to the WO included in the selected index when a current request of read retry for the selected block is received. As described above, read retry is repeated at a read level of other index of the read retry table until a read error is corrected.

As a result, if the read error is corrected (YES in S1040), read error correction is completed (S1060). In contrast, if the read error is not corrected by a read level of the last index of the read retry table (NO in S1040), the read method of FIG. 10 uses other read error correction scheme to correct the read error (S1080). For example, if the read error is not corrected by the read level of the last index of the read retry table, the read method of FIG. 10 performs a read correction operation using soft decision by a low density parity check code (LDPC) method. The LDPC is a method to correct an error based on hard decision information obtained through hard decision read and reliability information obtained through soft decision read.

As such, according to the read method according to another exemplary embodiment of the present inventive concept, the frequency of read retries may be reduced and, when a read error is not corrected by read retry, an entry in another read error correction scheme may be advanced. Thus, both overall read performance and reliability of a memory system may be improved.

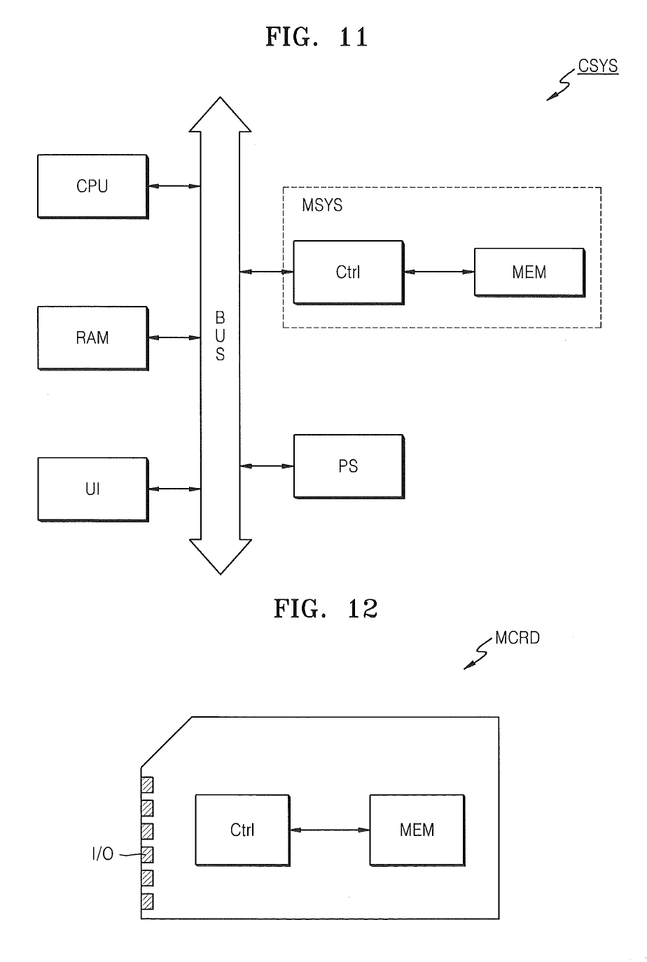

A computing system CSYS according to an exemplary embodiment of the present inventive concept includes a processor CPU, a user interface UI, and a flash memory system MSYS which are electrically connected to bus BUS. The MSYS includes the Ctrl and the MEM. The MEM stores, via the Ctrl, N-bit data that is processed or to be processed by the CPU, where N is an integer that is equal to or greater than 1. The MSYS of FIG. 11 may be the MSYS of FIG. 2. Thus, according to the CSYS, reliability in reading the MSYS may be improved by simply control without any additional module.

The CSYS according to the present exemplary embodiment may further include a power supply unit PS. Also, when the MEM is a flash memory device executing a program by the program method of FIG. 2, the CSYS according to the present exemplary embodiment may further include a volatile memory device, for example, a RAM.

When the CSYS according to the present exemplary embodiment is a mobile apparatus, a battery for supplying an operation voltage of the CSYS and a modem such as a baseband chipset may be further provided. Also, it is obvious that the CSYS according to the present exemplary embodiment may be further provided with an application chipset, a camera image processor (CIS), a mobile DRAM, etc., of which descriptions are omitted herein.

FIG. 12 is a block diagram of a memory card MCRD according to an exemplary embodiment of the present inventive concept. Referring to FIG. 12, the MCRD according to the present exemplary embodiment includes the Ctrl and the MEM. The Ctrl controls data write to the MEM or data read from the MEM in response to a request of an external host (not shown) that is received through an input/output unit I/O. Also, the Ctrl controls an erase operation on the MEM. The Ctrl of the MCRD according to the present exemplary embodiment may include interface units (not shown) for interfacing with the host and a memory device, a RAM, etc. to perform the above control operation. The MCRD according to the present exemplary embodiment may be embodied by the MSYS of FIG. 2.

The MCRD of FIG. 12 may be embodied by a compact flash card (CFC), a microdrive, a smart media card (SMC), a multimedia card (MMC), a security digital card (SDC), a memory stick, a USB flash memory driver, etc. Accordingly, according to the MCRD of FIG. 12, read reliability may be improved and overhead of a system may be reduced.

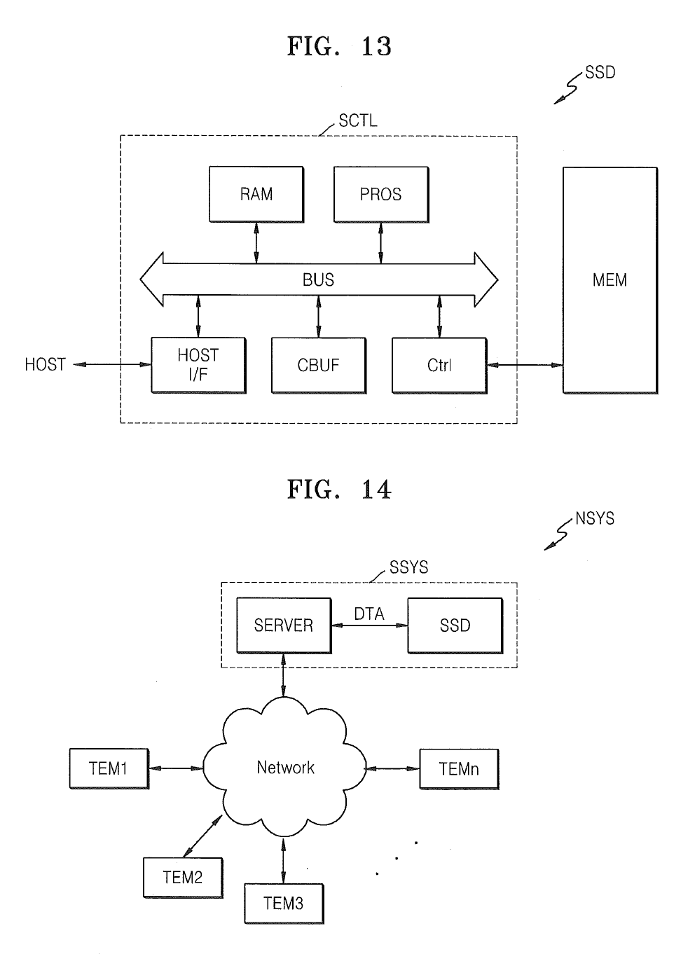

FIG. 13 illustrates a solid state drive (SSD) according to an exemplary embodiment of the present inventive concept. Referring to FIG. 13, the SSD according to the present exemplary embodiment includes an SSD controller SCTL and the MEM. The SCTL may include a processor PROS, a RAM, a cache buffer CBUF, and the memory controller Ctrl, which are connected by bus BUS. The PROS in response to a request (command, address, data) of a host (not shown) controls the Ctrl to transmit and receive data with respect to the MEM. The PROS and the Ctrl of the SSD according to the present exemplary embodiment may be embodied by a single ARM processor. Data needed for the operation of the PROS may be loaded in the RAM. For example, the TAB of FIG. 2 may be loaded in the RAM.

A host interface HOST I/F receives a request of a host and transmits data to the PROS or transmits data received from the MEM to the host. The HOST I/F may interface with the host by using various interface protocols such as universal serial bus (USB), man machine communication (MMC), peripheral component interconnect-express (PCI-E), serial advanced technology attachment (SATA), parallel advanced technology attachment (PATA), small computer system interface (SCSI), enhanced small device interface (ESDI), intelligent drive electronics (IDE), etc. The data to be transmitted to the MEM or received from the MEM may be temporarily stored in the CBUF. The CBUF may be an SRAM.

The SSD according to the present exemplary embodiment may be embodied by the MSYS of FIG. 2. Accordingly, according to the SSD of FIG. 13, the frequency of read retries is reduced so that read reliability may be improved and overhead of a system may be reduced.

FIG. 14 illustrates a server system including an SSD and a network system. Referring to FIG. 14, a network system NSYS according to the present exemplary embodiment may include a server system SSYS connected via a network and a plurality of terminals TEM1-TEMn. The SSYS according to the present exemplary embodiment may include a server SERVER for processing a request received from a plurality of terminals TEM1-TEMn connected to a network and an SSD for storing data corresponding to a request received from the terminals TEM1-TEMn. The SSD of FIG. 14 may be the SSD of FIG. 13. That is, the SSD of FIG. 14 may include the SCTL and the MEM. The MEM may be a flash memory device that performs read by the read method of FIG. 1.

As described above, in the flash memory system and a read method of the flash memory system according to the present inventive concept, the frequency of read retries may be reduced in performing read retry on a memory block where an error is found. Thus, deterioration of read reliability due to high integration may be prevented.

While the present inventive concept has been particularly shown and described with reference to preferred embodiments using specific terminologies, the exemplary embodiments and terminologies should be considered in descriptive sense only and not for purposes of limitation.

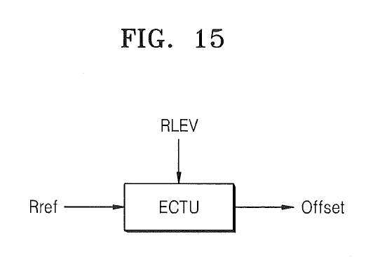

For example, in the above description, an example that the CMD_RR is performed at the RLEV set by the ECTU is described, but the present inventive concept is not limited thereto. According to the present exemplary embodiment, the ECTU may detect offset indicating a difference between the RLEV and a reference level Rref, as illustrated in FIG. 15. As described above, the Ctrl of FIG. 2 may include a separate unit for performing read control in response to an output of the ECTU. The unit for performing read control may control that read retry be performed at a voltage level changed from the Rref by the offset of FIG. 15.

While the inventive concept has been particularly shown and described with reference to exemplary embodiments thereof, it will be understood that various changes in form and details may be made therein without departing from the spirit and scope of the following claims.

What is claimed is:

1. A method of operating a nonvolatile memory device, comprising:
reading a first plurality of nonvolatile memory cells within a first block of the nonvolatile memory device using a first plurality of read voltage levels to assess the program states of the first plurality of nonvolatile memory cells;
identifying at least one error in first data obtained from said reading a first plurality of nonvolatile memory cells; and
rereading the first plurality of nonvolatile memory cells using a first plurality of updated read voltage levels derived from a first selected index in a read retry table that corresponds to a wear-out degree associated with the first block of the nonvolatile memory device.

2. The method of claim 1, further comprising identifying at least one error in second data obtained from said rereading the first plurality of nonvolatile memory cells using a first plurality of updated read voltage levels; and rereading the first plurality of nonvolatile memory cells using a second plurality of updated read voltage levels derived from a second selected index in the read retry table, which differ at least partially from the first plurality of updated read voltage levels.

3. The method of claim 2, further comprising identifying at least one error in third data obtained from said reading a first plurality of nonvolatile memory cells using a second plurality of updated read voltage levels; and then correcting the at least one error in the third data using a low density parity check code.

4. The method of claim 3, further comprising updating the read retry table in response to a change in a wear-out degree associated with the first block of the nonvolatile memory device.

5. The method of claim 1, further comprising updating the read retry table in response to a change in a wear-out degree associated with the first block of the nonvolatile memory device.

6. A read method in a flash memory system including a flash memory and a memory controller, the read method comprising:
updating a selected one of indexes of a selected one of blocks of the flash memory, in a wear-out table for indexing each of the blocks of the flash memory; and
setting a start read level to start read retry on the selected block by referring to a read retry table corresponding to a wear-out degree included in the selected index when a current request of read retry on the selected block is received.

7. The read method of claim 6, wherein the read retry table corresponding to the wear-out degree included in the selected index is one of read retry tables separately provided for each endurance state of the flash memory.

8. The read method of claim 6, wherein the read retry table corresponding to the wear-out degree included in the selected index has a read environment of the flash memory as an index.

9. The read method of claim 8, wherein the read environment is at least one of a retention characteristic and a read disturb characteristic of the flash memory.

10. The read method of claim 6, wherein the selected index comprises a wear-out degree of the selected block, and information of an index corresponding to a read level at which a read error is corrected by a previous request for read retry on the selected block among the indexes of the read retry table.

11. The read method of claim 6, further comprising repeating a read operation at each voltage level from the start read level to a last read level of a last index of a read retry table corresponding to a wear-out degree included in the selected index, until an error that is a basis for a current request of the read retry is corrected.

12. The read method of claim 11, further comprising starting a read correction operation that is different from read retry when the error is not corrected by a read operation at the last read level of the last index of a read retry table corresponding to a wear-out degree included in the selected index.

13. The read method of claim 12, wherein the read correction operation that is different from read retry is a read correction operation by soft decision in a low density parity check code (LDPC) method.

14. A memory system comprising:
a flash memory comprising a plurality of blocks and detecting information about a state of a selected block in response to a first command; and
a memory controller transmitting the first command to the flash memory and setting a read level to start read retry on the selected block by referring to a read retry table corresponding to the information about a state, of read retry tables separately included for each endurance state, when a current request of read retry on the selected block is received.

15. The memory system of claim 14, wherein each of the read retry tables comprises at least one of a retention characteristic and a read disturb characteristic of the flash memory as an index.

16. The memory system of claim 15, wherein the memory controller updates a selected index on the selected block of the indexes in a wear-out table for indexing each of the blocks of the flash memory based on the state information.

17. The memory system of claim 16, wherein the memory system further comprising an error control unit for setting a read level to start read retry on the selected block based on index information of a read retry table corresponding to a previous request of read retry included in the selected index.

18. The memory system of claim 14, wherein the first command is an erase command.

19. The memory system of claim 17, wherein the state information in response to the erase command corresponds to an incremental step pulse erase (ISPE) loop count value used to erase the selected block.

20. The memory system of claim 14, being included in a solid state drive.
